(19) United States
(12) Patent Application Publication
(10) Pub. No.: US 2010/0020518 A1
(43) Pub. Date: Jan. 28, 2010

(54) RF shielding arrangement for semiconductor packages

(75) Inventor: Ulysses T. Bustamante, Warren, NJ (US)

Correspondence Address: WILLIAM L BOTJER, P O BOX 478, CENTER MORICHES, NY, 11934, US

(73) Assignee: ANADIGICS, INC.

(21) Appl. No.: 12/220,757

(22) Filed: Jul. 28, 2008

(51) Int. Cl. H05K 9/00; H01L 21/50

(52) U.S. Cl. 361/818; 174/377; 438/106; 257/E21.499

(57) ABSTRACT

A packaging for semiconductor modules such as multi chip modules (MCM). At least one via is created on saw street region of a substrate having circuit components. The substrate is transfer molded and the transfer molded substrate is partially singulated from a first surface along with the via to create a groove. The partially singulated substrate including the groove on the saw street region and the via is coated or plated with a conducting material for RF shielding. Accordingly, the conducting material and a ground terminal of the substrate are connected through the via on the substrate.

### BACKGROUND

The present invention relates to semiconductor packages. More particularly, the present invention relates to semiconductor packages capable of incorporating radio frequency shielding.

Many electronic assemblies such as Printed Circuit Boards (PCB), multi-chip modules (MCM), System in Package (SIP), etc., contain components which are sensitive to radio frequency (RF) signals or which emit RF signals. RF interference, also known as electromagnetic interference (EMI), is an important factor in determining the functionality and proper performance and conformance to regulations of electrical assemblies. Many components included within a printed circuit board (PCB) assembly may emit RF signals and numerous regulations exist which limit the amount or extent of RF emission that may occur from an electrical or electronic device. In addition, certain components contained within the assembly may be sensitive to RF interference. In order to comply with regulations and to protect sensitive components from RF interference, RF shields are often placed around critical components like an RF power amplifier module. An RF shield is a conductive structure (typically metal) that prevents radio frequency electromagnetic radiation from entering, leaving, or passing through the shield. Typically, these shielded metallic enclosures are made from a conductive material that is electrically coupled to an appropriate ground.

In existing systems, shielded enclosures have been made by attaching a drawn metallic casing over the molded semiconductor module package and soldering the metal casing to a substrate connected to the printed circuit components. However, this method of shielding is costly and cumbersome and may affect the circuit components.

In light of the foregoing, there is a need of for a method to efficiently RF shield a semiconductor module before completing the assembly process.

### SUMMARY

The present invention provides packaging for a semiconductor module. Different semiconductor microchips or circuit components are formed on a substrate or laminate of the semiconductor module. The substrate has a first surface and a second surface. The circuit components are constructed on the first surface and the second surface is connected to a ground pad and to input/output terminals of the semiconductor module. The method includes creating at least one via on a saw street region of the substrate, molding the first surface of the substrate with a molding compound, partially sawing the transfer molded substrate from the first surface and extending vertically towards the second surface by using cutting tools to create a groove on the saw street region and the at least one via, and plating the partially singulated substrate including the groove on the saw street region and the partially cut via with a conducting material providing radio frequency shield for the circuit components. Accordingly, the radio frequency shield is connected to the ground pad of the substrate through the at least one via. As a next step, the substrate is sawed from the second surface to completely singulate the semiconductor module and thereby completing the process.

Grounding the RF shield through the via on the substrate provides a good electrical connection between the circuit components and an effective EMI/RFI shield of the semiconductor module package. By shielding the semiconductor module package in this manner, external metal shields, as taught in the prior art, are no longer necessary. Further, high temperatures are not transmitted to the circuit components during the RF shield attachment process and the additional thickness or bulk associated with the RF shield is avoided. Further, this also saves area and reduces the height of the semiconductor module package. Moreover, the complete process becomes cost effective due to elimination of external metal shield and efficient as a number of associated processes are removed.

### BRIEF DESCRIPTION OF DRAWINGS

FIG. 1 illustrates a cross section of a packaged semiconductor module in accordance with an embodiment of the invention; and

FIG. 2 is a flow chart illustrating a method for forming a packaged semiconductor module in accordance with an embodiment of the invention;

FIG. 3 illustrates the connection between a shield and a ground pad of the substrate in accordance with FIG. 1 and FIG. 2; and

FIGS. 4a, 4b illustrate the arrangement of via in a single layer and in a multi-layer substrate in accordance with an embodiment of the invention.

### DESCRIPTION OF THE PREFERRED EMBODIMENTS

Various embodiments of the invention provide a method for packaging a semiconductor module including circuit components. Herein, at least one via is constructed on a substrate having the circuit components. The substrate is molded or encapsulated with a molding compound and then partially singulated from the top to create a groove on a saw street region along with the at least one via. The substrate along with the molding compound and the groove on the saw street region is plated with a conductive material. The conductive material provides a shield for the substrate and the circuit components from radio frequency and electromagnetic interference. Accordingly, a connection is established between a ground of the circuitry and the conductive material through the via. Hence, the via on the substrate functions a routing circuit for the semiconductor module.

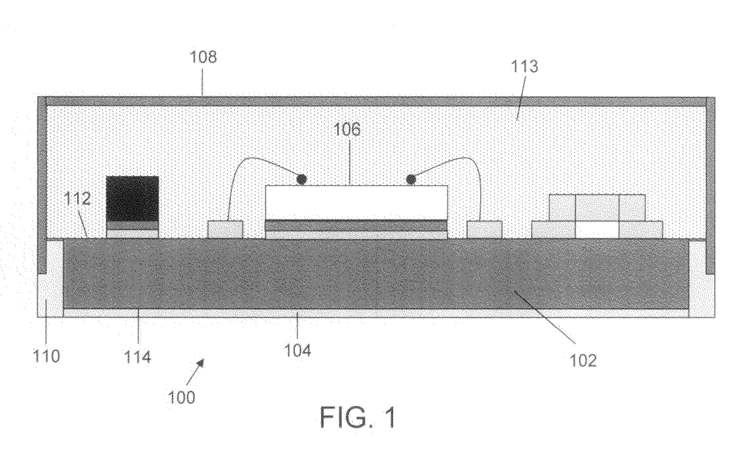

FIG. 1 is a diagram illustrating a cross section of a packaged semiconductor module100 in accordance with an embodiment of the invention. Semiconductor module 100 may be a multi chip module (MCM), a printed circuit board (PCB) or system in package (SIP). Semiconductor module 100 includes a substrate 102, a ground pad 104, a plurality of semiconductor microchips and discrete circuit components 106 hereinafter referred to as circuit components 106, a shield 108 and a via 110. Substrate 102 has a first surface 112 and a second surface 114. First surface 112 is positioned opposite to second surface 114.

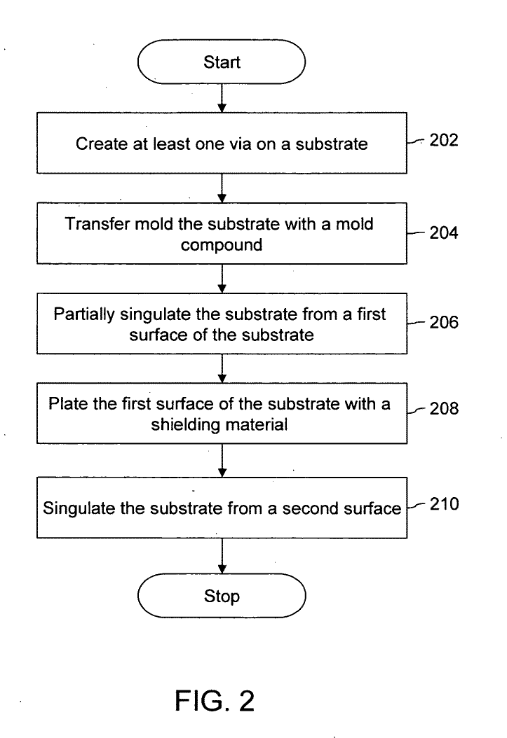

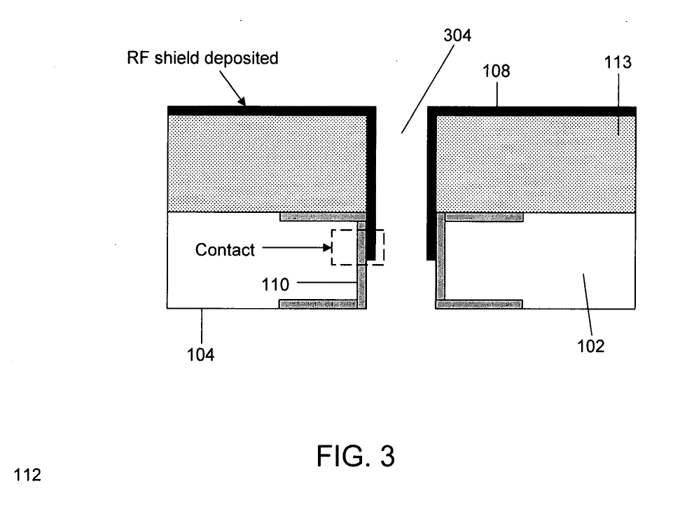

Via 110 is constructed on substrate 102 in a saw street region (not shown) of substrate 102. Further, circuit components 106 are constructed on first surface 112 of substrate 102. In other words, substrate 102 functions as a circuit carrier. Circuit components 106 and ground pad 104 are connected through via 110. Ground pad 104 is connected to second surface 114 of substrate 102. Ground pad 104 functions as a ground terminal for circuit components 106. Circuit components 106 are covered by shield 108. Shield 108 is deposited on first surface 112 of substrate 102 on top of molded circuit components 106. In accordance with an embodiment of the invention, a molding compound 113 is deposited on first surface 112 of substrate 102 and shield108 is then deposited on molding compound 113. Shield 108 is made of a conductive material such as metal, conductive plastic, and the like. Shield 108 protects circuit components 106 from radio frequency or electromagnetic interference. Shield 108 is connected to ground pad 104 by means of via 110. The connection is established by partially singulating substrate 102 from first surface 112 along with molding compound 113 and via 110 and then depositing the conductive material. Substrate 102 is then singulated from second surface 114. In an embodiment of the invention, substrate 102 is singulated 50% or more from first surface and then shield 108 is deposited. This is further explained in detail in conjunction with FIG. 2 and FIG. 3.

In accordance with various embodiments of the invention, substrate 102 may be made from any one of a number of materials commonly used in the industry, such as epoxy, polyester, polyimide, polyetherimide, polytetrafluroethylene, glass-reinforced printed circuit board material, metal, ceramic, and the like. Substrate 102 may be a single layer substrate. Substrate 102 may also be a multi-layer substrate. Further, substrate 102 may be rigid or flexible.

In accordance with various embodiments of the invention, circuit components 106 are interconnected circuits and components such as microchips or individual components. Circuit components 106 are printed on substrate 102 and soldered to the interconnecting circuits.

In accordance with various embodiments of the invention, via 110 may be a blind via or a plated through hole.

FIG. 2 is a flowchart of a method for forming a packaged semiconductor module in accordance with an embodiment of the invention. At step 202, at least one via such as via 110 is created on saw street region of the substrate such as substrate 102. The via refers to a pad with a plated hole that connects the copper tracks from one layer of the semiconductor module to other layers. Alternatively, the via is a plated through hole for providing an electrical connection between the circuit components such as circuit components 106 printed on the substrate. In one embodiment of the invention, the via is a blind via. In another embodiment of the invention, the via is a plated through hole (PTH). In accordance with various embodiment of the invention, size of the via is about 300 micrometer (in diameter) with 75 micrometer capture pad.

At step 204, the substrate is transfer molded with a molding compound. Transfer molding is performed for encapsulation purposes. Molding compound 113 is deposited on the first surface of the substrate substantially covering the first surface. Examples of molding compound 113 include a non-conductive material, such as non-conductive thermoset plastic, polymers and the like. Molding compound 113 is deposited such that it provides a sealing effect or functions as a barrier to the outside environment protecting the semiconductor microchips and discrete components. In accordance with various embodiments of the invention, the transfer molding is performed by using available transfer molding tools. At step 206, the substrate along with the mold is partially (preferably 50% or more to have adequate electrical connection) singulated from the first surface extending longitudinally towards the second surface to create a groove/KERF along the saw street region. The substrate is sawed through the via. The KERF is a groove or a notch made by using a cutting tool. The sawing is performed along singulation or scribe streets that are predetermined based on the dimensions of the circuit components. The sawing may be performed by using laser beam cutting tools, a metallized or resin-bonded diamond saw blade rotating at a high speed.

Thereafter, at step 208, the first surface of the substrate is plated with a shielding material including the groove and the partially cut via. The shielding material is a conductive material that provides protection specifically from radio frequency interference and electromagnetic interference. Examples of the conductive material include metals such as copper, tin, stainless steel, and the like. Metals having a melting temperature lower than the melting/decomposition temperature of the underlying non-conductive material substrate are especially useful. In an embodiment of the invention, the conductive material may be a conductive plastic. Since, the groove is plated with the conductive material along with the partially cut via, the shielding material is connected to the via and in turn, with a ground pad of the substrate. Accordingly, the via is used as a connection between the circuit ground of the semiconductor module and the shielding material. At step 210, the substrate (remaining 50%) is sawed from the second surface to complete the process. Thereafter, the semiconductor module package is tested and shipped.

FIG. 3 is a block diagram illustrating the connection between the ground pad and the shield in accordance with FIG. 1 and FIG. 2. As shown in FIG. 3, a groove/KERF 304 is created by first partially sawing transfer molded substrate 102 from first surface 112. Transfer molded substrate is coated/plated with shield108 for RF/EMI shielding. Via 110 on the substrate is connected to shield108 and accordingly it is connected to the ground pad as illustrated. Substrate 102 is sawed completely (remaining portion) from second surface 114 of substrate 102.

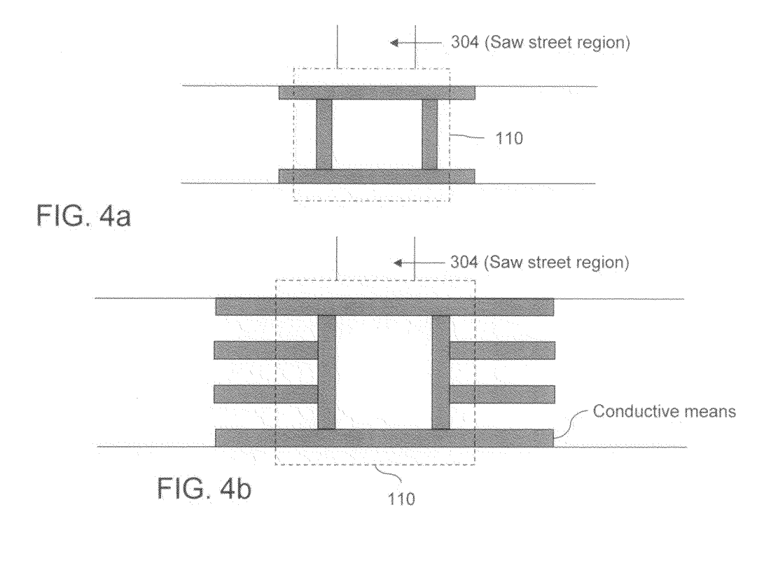

FIGS. 4a, 4b illustrate the arrangement of via 110 in a single layer and in a multi-layer substrate in accordance with an embodiment of the invention. As shown in FIG. 4b, in a multi-layer substrate arrangement, plated through hole or blind vias are constructed which provide the necessary interconnection between copper tracks from one layer of the board to the other layers. Further, the copper tracks function as conductive means and provide connection with the ground pad of the substrate on which the semiconductor components are mounted. The molding compound is then deposited on the semiconductor components followed by the deposition of conductive material on the molding compound. The layer of the conductive material functions as an RF shield. The substrate is singulated from the top surface through the via to establish the connection between the shield and the ground pad of the substrate. Similar arrangement of via in a two-layered substrate is shown in FIG. 4a.

The method and system described above have a number of advantages. Since shielding is included as a part of the packaging process, external metal shields, as taught in the prior art, are no longer necessary. Further, high temperatures are not transmitted to the semiconductor modules or circuit components on the printed circuit board during the RF shield deposition process and the additional thickness or bulk associated with the RF shield is avoided. Further, the complete process becomes cost effective and efficient as associated process is eliminated.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

What is claimed is:

1. A method for packaging a semiconductor module, the semiconductor module comprising a substrate, and a plurality of circuit components, the plurality of circuit components being formed on the substrate, the method comprising the steps of:
creating at least one via on the saw street region of the substrate;
transfer molding a first surface of the substrate with a molding compound;
partially singulating the transfer molded substrate from the first surface of the substrate to create a kerf on the saw street region, wherein the singulation is performed through the molding compound and the at least one via;
plating the transfer molded substrate with a shielding material, wherein a ground pad of the substrate is connected to the shielding material through the at least one via; and
singulating the substrate from a second surface, the second surface being opposite to the first surface.

2. The method according to claim 1 wherein the shielding material is a conductive material, the conducting material providing a radio frequency interference shield or an electromagnetic interference shield.

3. The method according to claim 1 wherein the substrate is a single layer substrate.

4. The method according to claim 1 wherein the substrate is a multi-layer substrate.

5. The method according to claim 1 wherein the at least one via is a blind via.

6. The method according to claim 1 wherein the at least one via is a plated through hole via.

7. A packaging arrangement for a printed circuit board having a plurality of semiconductor components mounted thereon, comprising:
a substrate, the substrate mounting the plurality of semiconductor components;
a ground pad on the lower surface of the substrate;
at least one via on the substrate, the via comprising conductive means connected to the ground pad;
a non conductive molding compound surrounding the plurality of semiconductor components; and
a conductive material deposited on said molding compound to from an RF shield, the conductive material being electrically connected to the at least one via and thereby to the ground pad.

8. The arrangement according to claim 7 wherein the conductive material deposited on the molding compound comprises a metal.

9. The arrangement according to claim 7 wherein the conductive material deposited on the molding compound comprises a conductive plastic.

10. The arrangement according to claim 7 wherein the at least one via is a plated through hole via.

11. The arrangement according to claim 7 wherein the substrate is a single layer substrate.

12. The arrangement according to claim 7 wherein the substrate is a multi layer substrate.

13. The arrangement according to claim 7 wherein at least one via is a blind via.
